(19) United States
(12) Patent Application Publication
(10) Pub. No.: US 2020/0091173 A1
(43) Pub. Date: Mar. 19, 2020

(54) SEMICONDUCTOR DEVICE AND MANUFACTURING METHOD THEREOF

(71) Applicant: Toshiba Memory Corporation, Minato-ku (JP)

(72) Inventors: Osamu MIYAGAWA, Yokkaichi (JP); Takahiro TOMIMATSU, Yokkaichi (JP)

(73) Assignee: Toshiba Memory Corporation, Minato-ku (JP)

(21) Appl. No.: 16/281,334

(22) Filed: Feb. 21, 2019

(30) Foreign Application Priority Data
Sep. 14, 2018 (JP) 2018-172304

(51) Int. Cl. H01L 27/11582; H01L 21/311

(52) U.S. Cl. CPC H01L 27/11582; H01L 21/31116

(57) ABSTRACT

A semiconductor device according to one embodiment includes a semiconductor substrate and a stack body including first films and second films alternately stacked in a first direction perpendicular to the semiconductor substrate, and including a stepped end portion. Each of the first films has a thick film portion located on the end portion, and an eave portion hanging over from a upper part of the thick film portion to the side in a second direction parallel to the semiconductor substrate.

### CROSS-REFERENCE TO RELATED APPLICATIONS

This application is based upon and claims the benefit of priority from Japanese Patent Application No. 2018-172304, filed on Sep. 14, 2018; the entire contents of which are incorporated herein by reference.

### FIELD

The embodiments of the present invention relate to a semiconductor device and a manufacturing method thereof.

### BACKGROUND

A three-dimensional semiconductor memory being an example of a semiconductor device includes a stack body in which two types of films are alternately stacked. An end portion of the stack body is processed in a stepped form. The films of one of the two types are connected to contacts at respective steps of the end portion.

In the semiconductor memory as described above, contacts with different depths need to be formed with increase in the number of stacked films. When deep contacts and shallow contacts are to be formed simultaneously, the films are likely to be damaged and pierced through during processing of the contacts if the films do not have a sufficient selectivity with respect to the contact processing.

### BRIEF DESCRIPTION OF THE DRAWINGS

FIG. 1 is a sectional view illustrating a structure of an end portion of a semiconductor device according to one embodiment;

FIG. 2 is an enlarged view of parts of metal films extracted from the semiconductor device illustrated in FIG. 1;

FIG. 3 is a sectional view for explaining a step processing process;

FIG. 4 is a sectional view for explaining a film formation process;

FIG. 5 is a sectional view for explaining an etching process;

FIG. 6 is a sectional view for explaining another film formation process;

FIG. 7 is a sectional view for explaining another etching process;

FIG. 8 is a sectional view for explaining a film formation process of an interlayer film; and

FIG. 9 is a sectional view for explaining a formation process of a contact hole.

### DETAILED DESCRIPTION

Embodiments will now be explained with reference to the accompanying drawings. The present invention is not limited to the embodiments.

A semiconductor device according to an embodiment comprises a semiconductor substrate and a stack body including first films and second films alternately stacked in a first direction perpendicular to the semiconductor substrate, and including a stepped end portion. Each of the first films has a thick film portion located on the end portion, and an eave portion hanging over from a upper part of the thick film portion to the side in a second direction parallel to the semiconductor substrate.

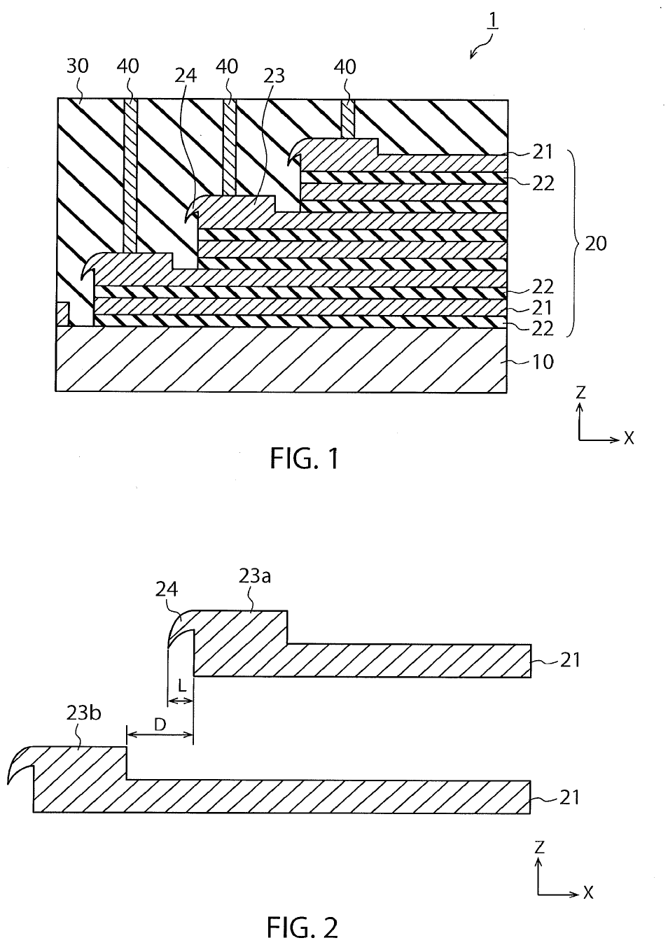

FIG. 1 is a sectional view illustrating a structure of an end portion of a semiconductor device according to one embodiment. A semiconductor device 1 illustrated in FIG. 1 is a three-dimensional semiconductor storage device in which word lines are stacked. Specifically, the semiconductor device 1 includes a semiconductor substrate 10, a stack body 20, an interlayer film 30, and contacts 40.

The semiconductor substrate 10 is, for example, a silicon substrate. The stack body 20 is located on the semiconductor substrate 10. While the stack body 20 is located directly on the semiconductor substrate 10 in the present embodiment, a foundation layer including elements and wires required for driving of memory cells (not illustrated) may be, for example, formed between the semiconductor substrate 10 and the stack body 20.

Metal films 21 and insulating films 22 are alternately stacked in a Z direction in the stack body 20. The metal films 21 contain metal such as tungsten and function as word lines. The insulating films 22 are formed as, for example, silicon dioxide films (SiO₂).

An end portion of the stack body 20 is processed in a stepped form as illustrated in FIG. 1. The metal films 21 are an example of first films and the insulating films 22 are an example of second films. The Z direction corresponds to a first direction orthogonal to the semiconductor substrate 10. The first films may correspond to insulating films 210 described later.

Thick film portions 23 are provided at end portions of the metal films 21. The thick film portions 23 can enlarge processing margins of the contacts 40 in the Z direction. Further, eave portions 24 hang over to the side in an X direction from upper parts of the thick film portions 23 in the metal films 21. The X direction corresponds to a second direction orthogonal to the Z direction and parallel to the semiconductor substrate 10. Due to the eave portions 24, processing margins of the contacts 40 in the X direction can be enlarged.

FIG. 2 is an enlarged view of parts of the metal films 21 extracted from the semiconductor device 1 illustrated in FIG. 1. In the present embodiment, a length L of the eave portion 24 in the X direction is shorter than a distance D. The distance D is a distance in the X direction between a first thick film portion 23a connected to the eave portion 24 and a second thick film portion 23b located one step lower than the first thick film portion 23a. This restriction of the length L of the eave portion 24 prevents the leading end of the eave portion 24 from protruding toward the second thick film portion 23b. As a result, the insulating property between the metal films 21 can be secured.

Referring back to FIG. 1, the interlayer film 30 entirely covers the stack body 20. The interlayer film 30 is formed as, for example, a silicon dioxide film. The contacts 40 penetrate through the interlayer film 30 to be individually in contact with the thick film portions 23 on the respective steps. The contacts 40 contain a conductor such as tungsten. At the end portion of the stack body 20, the metal film 21 located on the lower side of each of the steps is connected to a contact (not illustrated) at a position not illustrated in FIG. 1. At that position, the metal film 21 and the insulating film 22 located on the upper side of each of the steps are exposed and the metal film 21 on the lower side has the thick film portion 23.

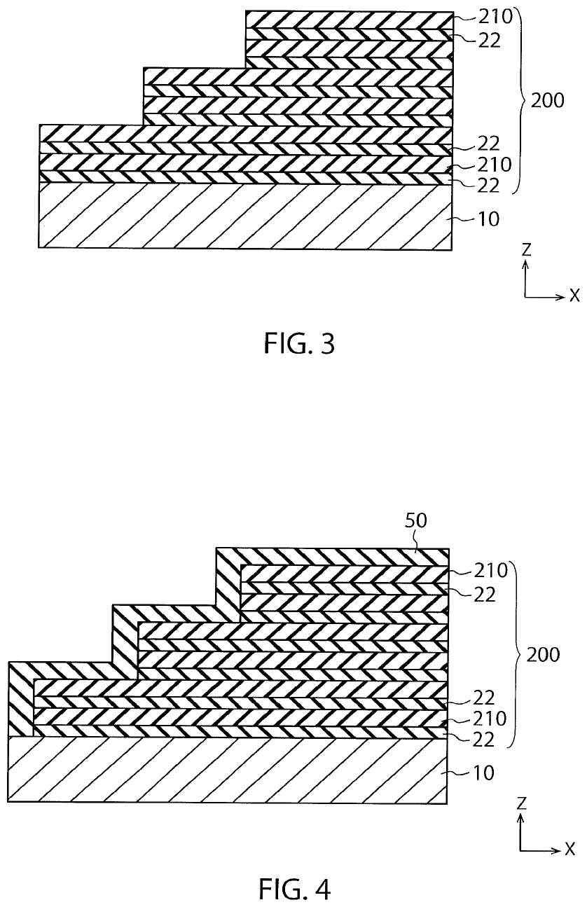

A manufacturing method of the semiconductor device 1 according to the present embodiment described above is explained below with reference to FIGS. 3 to 9.

First, as illustrated in FIG. 3, an end portion of a stack body 200 formed on the semiconductor substrate 10 is processed in a stepped form. In the stack body 200, the insulating films 210 and the insulating films 22 are alternately stacked in the Z direction. The insulating films 210 are formed as, for example, silicon nitride films (SiN). In a step processing process illustrated in FIG. 3, topmost layers of respective steps are the insulating films 210.

Next, a film 50 is formed as illustrated in FIG. 4. As a result, the film 50 entirely covers the end portion of the stack body 200. The film 50 is an example of a third film of the same material as that of the insulating films 22. In the present embodiment, the film 50 is a silicon dioxide film. The film 50 can be formed using, for example, a CVD (Chemical Vapor Deposition) method or an ALD (Atomic Layer Deposition) method.

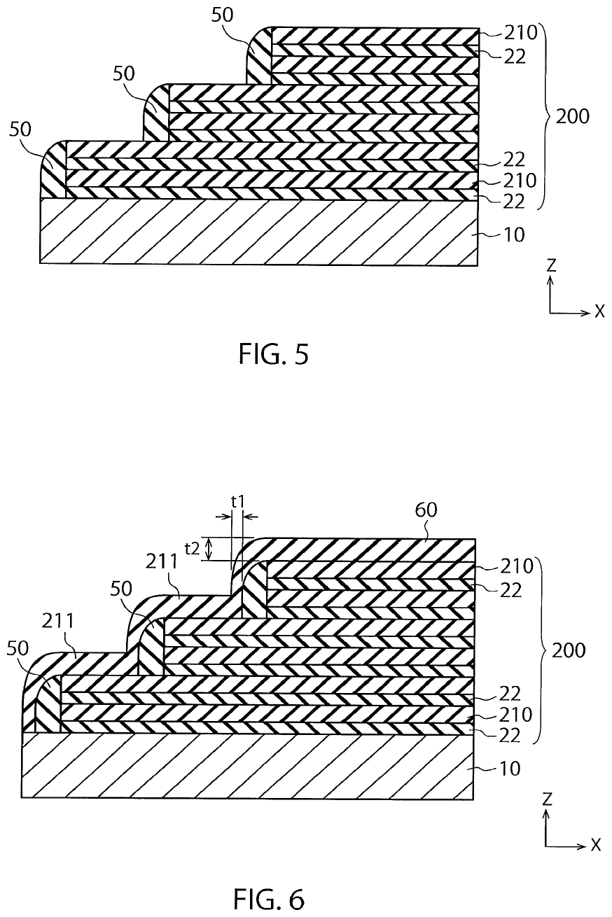

Next, the film 50 is etched in the Z direction by RIE (Reactive Ion Etching). As a result, the insulating films 210 on the topmost layers of the respective steps are exposed as illustrated in FIG. 5. Meanwhile, parts of the film 50 remain on riser portions of the end portion of the stack body 200, in other words, on side surfaces of the insulating films 210 and the insulating films 22. Because RIE (Reactive Ion Etching) is used in an etching process illustrated in FIG. 5, shoulder portions of the film 50 remaining on the riser portions are rounded.

Next, a film 60 is formed as illustrated in FIG. 6. As a result, the film 60 covers the film 50 remaining on the riser portions and the insulating films 210 exposed on the respective steps. The film 60 is an example of a fourth film of the same material as that of the insulating films 210. In the present embodiment, the film 60 is a silicon nitride film. The film 60 can be formed using, for example, a CVD method or an ALD method. With regard to the dimension of the film 60 covering the film 50 in the present embodiment, a thickness t1 in the X direction is smaller than a thickness t2 in the Z direction.

According to a film formation process illustrated in FIG. 6, due to formation of the film 60 of the same material as that of the insulating films 210, thick film portions 211 are formed at end portions of the insulating films 210, respectively. The thick film portions 211 correspond to the thick film portions 23 described above.

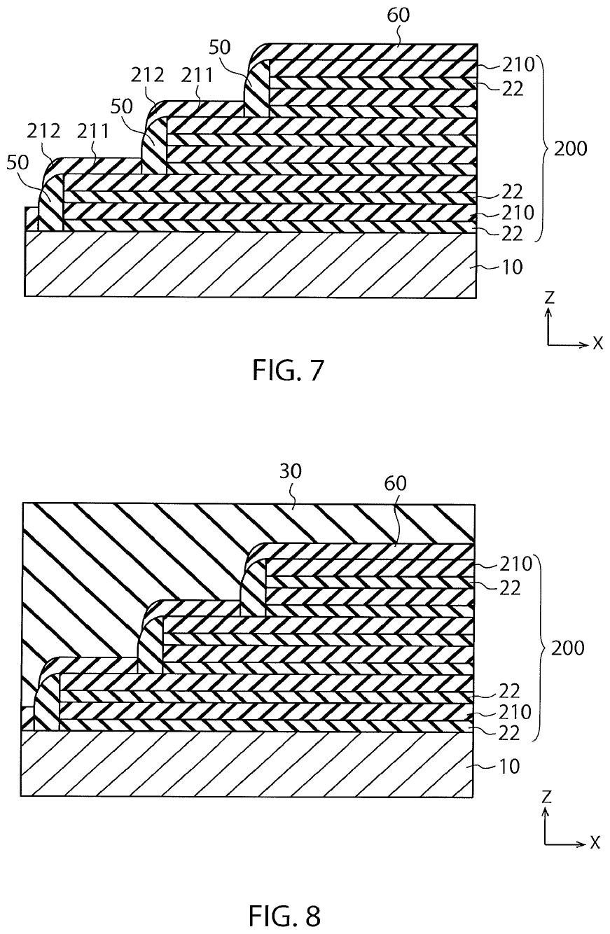

Next, as illustrated in FIG. 7, the film 60 is isotropically etched by a method such as RIE, wet etching, or CDE (Chemical Dry Etching). As described above, the thickness t1 in the X direction is smaller than the thickness t2 in the Z direction in the film 60 before etching. Therefore, parts of the film 60 that cover the side surface of the film 50 are removed by the isotropic etching.

According to a film formation process illustrated in FIG. 7, due to the etching of the film 60 covering the side surface of the film 50, eave portions 212 hanging over in the X direction from the thick film portions 211 are formed at the end portions of the insulating films 210, respectively. The eave portions 212 correspond to the eave portions 24 described above.

Next, the interlayer film 30 is formed as illustrated in FIG. 8. The interlayer film 30 can be formed using, for example, a CVD method or an ALD method. Thereafter, holes (not illustrated) penetrating through the stack body 200 are formed. Subsequently, the insulating films 210 and the film 60 are removed through the holes by wet etching. The metal films 21 are further formed at places from which the insulating films 210 and the film 60 have been removed. In this way, the insulating films 210 and the film 60 are replaced by the metal films 21.

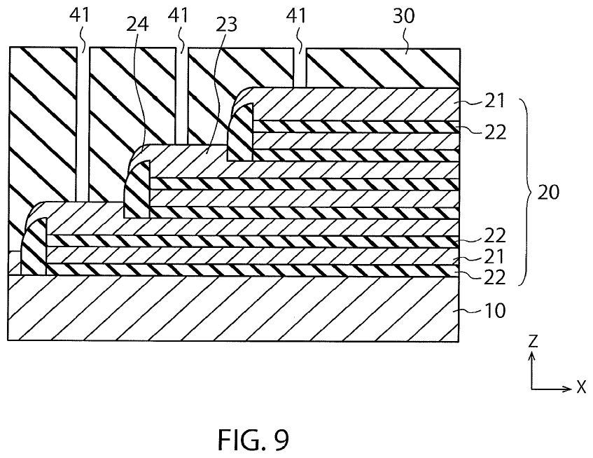

Next, as illustrated in FIG. 9, a plurality of contact holes 41 are formed. The contact holes 41 penetrate through the interlayer film 30 to reach the thick film portions 23 of the metal films 21, respectively. Finally, the contacts 40 are formed by embedding conductors in the contact holes 41, respectively. The semiconductor device 1 illustrated in FIG. 1 is thus completed.

In the embodiment described above, because the end portion of the stack body 20 is in a stepped form, the contact holes 41 including different depths are formed simultaneously. At that time, if the thickness of the metal films 21 is small, there is a possibility that the contact holes 41 penetrate through the metal films 21 located on upper ones of the steps.

However, because the metal films 21 have the thick film portions 23 in the present embodiment, processing margins in the Z direction are enlarged. Therefore, penetration of the contact holes 41 through the metal films 21 can be avoided.

If the lengths in the X direction on the respective steps of the end portion of the stack body, so-called terrace lengths are short, alignment of the contact holes 41 is difficult in the present embodiment. However, the eave portions 24 hang over in the X direction from the thick film portions 23 in the present embodiment. This enlarges the processing margins in the X direction and thus facilitates alignment of the contact holes 41.

Therefore, according to the present embodiment, the thick film portions 23 and the eave portions 24 can prevent the metal films 21 from being easily damaged during formation of the contacts 40. Accordingly, manufacturing yield can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a semiconductor substrate; and
a stack body including first films and second films alternately stacked in a first direction perpendicular to the semiconductor substrate, and including a stepped end portion, wherein
each of the first films includes a thick film portion located on the end portion, and an eave portion hanging over from a upper part of the thick film portion to a side in a second direction parallel to the semiconductor substrate.

2. The semiconductor device according to claim 1, wherein a length of the eave portion in the second direction is shorter than a distance in the second direction between a first thick film portion connected to the eave portion and a second thick film portion located one step lower than the first thick film portion.

3. The semiconductor device according to claim 1, wherein the first films are metal films and the second films are insulating films.

4. A manufacturing method of a semiconductor device, the method comprising:
processing an end portion of a stack body including first films and second films alternately stacked in a first direction perpendicular to a semiconductor substrate in a stepped form;
covering the end portion with a third film of a same material as that of the second film;
partially removing the third film to expose the first films on respective steps while leaving the third film on riser portions of the end portion;
covering the third film left on the riser portions and the first films exposed on the respective steps with a fourth film of a same material as that of the first films to form thick film portions on the first films; and
etching parts of the fourth film covering a side surface of the third film to form eave portions hanging over in a second direction parallel to the semiconductor substrate from upper parts of the thick film portions.

5. The manufacturing method of the semiconductor device according to claim 4, comprising:
forming the fourth film to have a thickness in the second direction to be smaller than that in the first direction; and
isotropically etching the fourth film to form the eave portions.

6. The manufacturing method of the semiconductor device according to claim 4, comprising forming a length of the eave portion in the second direction shorter than a distance in the second direction between a first thick film portion connected to the eave portion and a second thick film portion located one step lower than the first thick film portion.

7. The manufacturing method of the semiconductor device according to claim 4, comprising forming the first films as metal films and the second films as insulating films.
